(19) United States
(12) Patent Application Publication
(10) Pub. No.: US 2025/0015639 A1
(43) Pub. Date: Jan. 9, 2025

(54) SCANNING MIRROR FOR LASER POWER TRANSMISSION SYSTEM

(71) Applicant: Wi-Charge Ltd., Rehovot (IL)

(72) Inventors: Omer Nahmias, Aminadav (IL); Ortal Alpert, Ness Ziona (IL); Ilanit Shapir, Rehovot (IL); Lior Golan, Ramat Gan (IL); Alexander Slepoy, Chandler, AZ (US); Yan Rosh, Tel Aviv (IL); Ori Mor, Tel Aviv (IL); Eli Zlatkin, Tel Aviv (IL); Nir Simon, Kibbutz Ein Hashofet (IL)

(73) Assignee: Wi-Charge Ltd., Rehovot (IL)

(21) Appl. No.: 18/708,773

(22) PCT Filed: Nov. 9, 2022
(86) PCT No.: PCT/IL2022/051195

§ 371 Date: May 9, 2024

(30) Foreign Application Priority Data
Nov. 9, 2021 (IL) 287976

(51) Int. Cl. H02J 50/30; G02B 26/08; H02J 7/35

(52) U.S. Cl. CPC H02J 50/30; G02B 26/0816; H02J 7/35

(57) ABSTRACT

Systems for the aiming of a laser beam of wireless power towards the photovoltaic cell of a receiver, using an adjustable beam deflection unit, enabling accurate orientation of the mirror used to deflect the laser beam. Insufficient aiming accuracy may result in the spilling over of beam energy intended for absorption by the photovoltaic cell, into the surroundings. The criteria of accuracy and stability required of an electronically controlled beam aiming mirror must be such that the angular deviation of a beam, from the direction intended by the electronic control, is such that the level of optical power transferred into the surroundings, when a beam having the maximum power which the system can transmit is aimed at the target, does not exceed that allowed by a regulatory requirement. One common regulation limits the allowed dissipated power to the power of a class 3B laser.

### FIELD

The present invention relates to the field of laser based wireless power transmission, especially for use to accurately locate a wireless power receiver, and to prevent excessive transmission of laser power to the surroundings of the receiver.

### BACKGROUND

There exists a long felt need for the transmission of power to a remote location without the need for a physical wire connection. This need has become important in the last few decades, with the popularization of portable electronic devices operated by batteries, which need recharging periodically. Presently, the capacity of state of the art batteries and the typical battery use of a smart phone intensively used may be such that the battery may need charging more than once a day, such that the need for remote wireless battery recharging is important. Several prior art systems have been proposed for transmitting power safely to remote locations, which can be characterized as being at a distance significantly larger than the dimensions of the transmitting or receiving device. A typical configuration would be for the transmission of power to a receiver the size of a smart phone over a distance typical of a domestic room setting.

Photovoltaic cells allow transfer of optical power to mobile devices safely without wires, producing not more than 0.1 Watt for the size relevant to mobile phones when illuminated by either solar light or by available levels of artificial lighting in a normally lit room. At the same time, the typical battery of a portable electronic device has a capacity of between 1 and 100 Watt hour, and typically requires a daily charge, hence a much higher power transfer at a long range is needed. There is therefore an unmet need to safely transfer electrical power, over a large field of view and a range of up to a few meters, to portable electronic devices, which are typically equipped with a rechargeable battery.

Attempts have been made to transfer power in residential environments using laser beams. However, safety is a major concern. Moderate and high-power lasers are potentially hazardous because they can burn the retina of the eye, or even the skin. To control the risk of injury, various specifications, for example, in the US, the Code of Federal Regulations, title 21, volume 8, (21 CFR § 8), revised on April 2014, Chapter I, Subchapter J part 1040 deals with performance standards for light emitting products, including laser products. For wavelengths outside of the visible range, there exist, class 1, class 3B and class 4 lasers. Of currently allowed transmitted laser power levels outside the visible range, class 1 is considered safe for general public use and classes 3B and 4 are considered unsafe. However, the power levels achievable with class 1 lasers are generally insufficient to provide useful amounts of power without a complex safety system. Thus, there is a need to develop a system to allow safe use of higher power, non-visible laser beams for charging batteries remotely.

In such a remote charging system, a photovoltaic cell in or on the device to be charged, converts the optical power of the laser to electrical power, and uses the electrical power to charge the battery of the device. In order for the laser beam to search and find a photovoltaic cell to be charged, the current technology uses a scanning mirror as a beam deflector, such as is shown in US Published Patent Application No. 2017/0294809 for System for Optical Wireless Power Supply commonly owned by the present applicant. Scanning an area with a laser beam is used to locate the exact direction of a receiver relative to the transmitter. However, none of the known prior art discloses details of how to perform an efficient and specific method of scanning, to allow accurate and safe angular location of the receiver.

The disclosures of each of the publications mentioned in this section and in other sections of the specification, are hereby incorporated by reference, each in its entirety.

### SUMMARY

The systems of the present disclosure provide a solution which overcomes at least some of the disadvantages of prior art systems and methods, for the accurate aiming of a laser beam of a wireless power transmitter towards the photovoltaic cell of a receiver. The system uses an adjustable beam deflection unit, enabling accurate orientation of the mirror or mirrors to deflect the laser beam. Because the laser beam and the photovoltaic cell both have a small size (whether diameter or another lateral dimension) relative to the distance between them, accurate aiming of the laser beam is critical for optimal efficiency and safety. An accurately oriented mirror or set of mirrors increases the efficiency and safety of the laser charging system, firstly by ensuring the concentration of as much as possible of the laser beam on the photovoltaic cell, and secondly, by reducing the level of stray optical power directed into the surrounding environment. The latter safety feature operates not only by preventing spillage of potentially dangerously high laser power over the edge or edges of the receiver and into the surrounding area, but also by reducing any reflections of the power beam off the surface of the receiver in the region around the, as a result of inaccurate impingement of the beam of the photovoltaic cell. Using an inaccurately directed mirror may lead to inaccurate location of a receiver, which may lead to any of low efficiency, poor quality of service, or, more seriously, to a risk to users or bystanders.

In order to safely aim a laser at a small photovoltaic cell in such a way that a minimal fraction of the beam is directed into the environment, the laser beam must be sufficiently blocked by the receiver target, usually the photovoltaic cell, but also optionally including an absorbing or diffusing border region surrounding the photovoltaic cell region itself, hereinafter termed the photocell surround, so that only a minimal fraction of the beam impinges on possibly reflective parts of the receiver surface, or even spills over the edge of the receiver surface and into the environment. The photovoltaic cell and its surround must be large enough to accommodate the beam completely, or at least enough of the area of the beam so that the remaining power not absorbed by the target is within allowably safe limits. The photovoltaic cell must be large enough to absorb the beam, even if the cell with its surround, is tilted with respect to the beam, such that the beam's projection on the photovoltaic cell is larger than the cross-section of the beam.

Ideally, the size of the photovoltaic cell should be as large as possible in order to have the capacity to absorb all the power of the projected beam at any angle of impingement. However, given that the cost of a photovoltaic cell is size dependent, and, at least for the common application in a mobile telephone, that any area taken up by the photovoltaic cell and its surround reduces the area available for the screen, market considerations dictate that the cells be as small as possible. In addition, the smaller the cell, the higher its efficiency. Therefore, it is important to keep the cell size as small as possible, taking into account the beam size as mentioned above.

The present disclosure describes a system using lasers for safely charging a target photovoltaic cell. The upper power limit of class 3B lasers is 500 mW, and such lasers may be considered potentially dangerous to humans. The present system employs a beam deflection unit comprised of at least one rotatable mirror which adjusts the angle of the laser beam to accurately reach the target. Any power spilled beyond the target into the environment, either by reflection from the surface of the receiver, or by transmission over the edge of the receiver, should have levels below that of the upper allowable limit of a class 3B laser. The system also takes into account aiming accuracy resulting from vibration in the laser beam direction, whether arising from mechanical vibrations of the transmitter, or the pointing accuracy of the beam scanner, or jitter limitations of the electronic circuitry controlling the motion of the deflecting mirror or mirrors. By calculating and defining parameters of the laser beam relative to the receiver, the present invention discloses a system for safe, remote charging of electronic devices through photovoltaic cells.

an optical wireless power transmission system for transmitting a beam of optical power, the system comprising:

a transmitter comprising an orientable mirror having an operational field of view, the mirror orientation being electronically controlled by an input electronic signal, the transmitter adapted for transmitting the beam of optical power to a receiver comprising a photovoltaic cell adapted to convert the optical power of the beam to electrical power, at least the photovoltaic cell and its surround constituting a target, wherein the electronically controlled mirror has an aiming accuracy such that the angular deviation of a beam reflected from the mirror, from a direction intended by the electronic control, is smaller than:

$$\frac{{Size}_{target} ⋆ cos ( {FOV}_{max} ) - {D}_{class 3 B}}{R} ,$$

where:

Size_{target} is a distance between the two closest points on opposite edges of the target,

FOVₘₐₓ is the maximal angle between the beam and the normal to a surface of the photovoltaic cell, at which the receiver can receive a predetermined level of power transmission,

D_{cleam 3B} is an effective diameter of a cross section of the beam, outside of which the beam contains a total optical power within the limits of a class 3B laser at the wavelength of the beam of optical power, and R is the maximum range of a receiver to which the system is intended to transmit.

In such an optical wireless power transmission system, the target may comprise the photovoltaic cell and its border surround. Alternatively, the target may comprise the minimal lateral dimension of the face of the receiver in or on which the photocell is mounted.

In any of the above described systems, the mirror aiming accuracy may be such that when the electronic control aims the mirror at the central region of the photovoltaic cell, the maximum optical power transmitted into the environment is less than the power limit allowed for a class 3B laser.

Furthermore, the maximum optical power transmitted into the environment may arise from impingement of the beam beyond the edges of the target, and may comprise at least one of those parts of the beam reflected off a surface of the receiver outside the bounds of the target, or transmitted parts of the beam spilling over the edges of the receiver.

According to further implementations, in any of the optical wireless power transmission systems described in this application, the angular deviation of a beam reflected from the mirror, from a direction intended by the electronic control of the electronically controlled mirror, may arises from jitter in the input electronic signal. Alternatively, it may arise from at least one of electronic feedback loop jitter, driver noise level, conversion resolution of digital circuits generating the input electronic signal, and circuit noise, or from it may arise from the step increments of a mechanical driver generating the orientation of the mirror, or from mechanical vibration of the mirror.

Yet another implementation of the systems of the present disclosure involves an optical wireless power transmission system as described hereinabove, wherein the maximum angular rotational speed of the mirror is given by the expression:

$$\frac{N}{132000} + \frac{M ⋆ {r}^{2} ⋆ {N}^{2}}{2.16 ⋆ {10}^{14}} < 1$$

where:
N is the angular rotational speed in degrees per second,
r is the radius of the mirror motion, measured in mm, and
M is the mass of the mirror measured in grams.

There is further provided, according to yet further implementations of the optical wireless power transmission systems for transmitting a beam of optical power, as described in this application, a system comprising:
a transmitter comprising an orientable mirror electronically controlled by an input electronic signal, the transmitter adapted for transmitting the beam of optical power to a receiver comprising a photovoltaic cell adapted to convert the optical power of the beam to electrical power, at least the photovoltaic cell and its border surround constituting a target,
wherein the electronically controlled mirror is configured to have an aiming accuracy at least such that the angular deviation of a beam from a direction intended for its propagation by the electronically controlled mirror, is such that the level of optical power transferred into the environment, when a beam having the maximum power which the system can transmit is aimed at the target, does not exceed that allowed by a regulatory requirement applicable to a location where the system is authorized to operate.

In such an optical wireless power transmission system, the level of regulatory requirement may be the power limit allowed for a class 3B laser. In either of these cases, the level of optical power not absorbed by the photovoltaic cell and its border surround may comprise either power reflected from the surface of the receiver outside of the photovoltaic cell and its border surround, or parts of the optical beam spilling over the edges of the receiver.

Additionally, in any of the optical wireless power transmission systems described above, at least one element of the system may be marked with at least one indication of a regulatory requirement applicable to a location where the system is authorized to operate. Such an element may be a component part of the system or an operational manual of the system. Furthermore, the regulatory requirement may be that the total level of optical power transferred into the surroundings and not absorbed by the target, may be less than the power limits of a class 3B laser at the wavelength of the beam of optical power.

### BRIEF DESCRIPTION OF THE DRAWINGS

The presently claimed invention will be understood and appreciated more fully from the following detailed description, taken in conjunction with the drawings in which:

FIGS. 1A to 1C illustrate schematically a photovoltaic cell surrounded by a beam blocking border surround, together representing the target, with the target positioned between a laser and a power meter, absorbing a portion of the laser power; FIG. 1A shows the photovoltaic cell and its border surround, FIG. 1B shows a normally impinging laser beam and FIG. 1C shows the laser beam impinging at an angle on the photovoltaic cell;

FIG. 2A shows the laser beam incident on the target, illustrating the relevant parameters of the system for calculating the criteria for the allowed beam deviation from its intended path, and FIG. 2B is a graph showing the limits of the power of a class 3B laser beam plotted across the beam profile; and

FIG. 3 shows components of an exemplary configuration of an optical wireless power transmission system according to the present disclosure.

### DETAILED DESCRIPTION

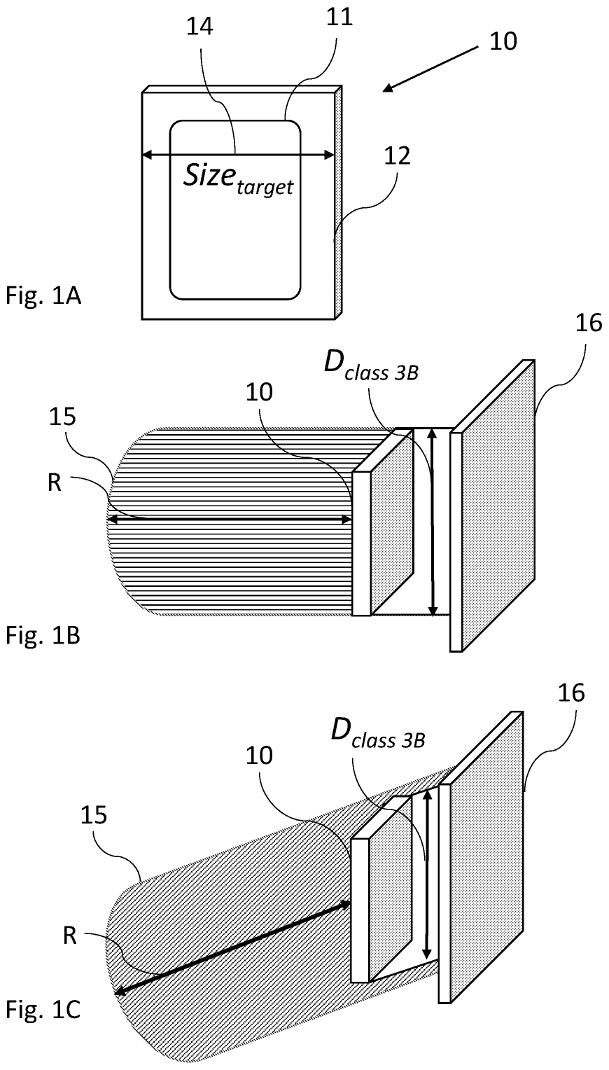

Reference is now made to FIG. 1A, which illustrates schematically a photovoltaic cell 11 surrounded by a beam block 12. According to the most common instance of the presently described system, in which the photovoltaic cell plus its surrounding absorbing or diffusing region, is mounted on the surface of the receiver, which may reflect back into the surroundings, part of the beam spilling onto it, the photovoltaic cell block 12, is herein considered to be the target 10. The typical target diameter or size 14 is characterized as the minimal length between points on opposite sides of the target, hereafter referred to as Size_{target}. In alternative instances of the presently described system, besides the reflection from the surface back into the surroundings, there is also need to consider any part of the beam that spills over the edge of the receiver and into the surroundings by means of direct transmission and not by reflection. If the surface of the receiver has a sufficiently low reflectivity to the incident beam that such reflection can be neglected, then the incursion of the beam into the environment occurs only through such spillover from the edge of the receiver. Thus, the target can be considered to be either the minimal lateral dimensions of the photocell and its surround, or the minimal lateral dimension of the face of the receiver into which the photocell is mounted, or a combination of the two. The exact definition of the target is thus dependent on the reflectance of the surface on which the photocell is mounted.

Reference is now made to FIG. 1B, in which there is shown a target 10 illuminated by a laser 15 directed normal to the target. Any of the beam spilling over the edges of the target would intrude into the surrounding environment, and the level of such environmental intrusion can be measured by the power meter 16 positioned behind the target. In the case of the target being mounted on a partially reflective surface, the power meter would also require an element positioned in the direction from which the beam was incident, in order to measure the reflected power also. In FIG. 1B, the size of the target, Size_{target}, is equal to or larger than the diameter D of the beam, such that no power from the beam spills beyond the target periphery, or is reflected from beyond the target periphery, for measurement by the power meter 16.

Reference is now made to FIG. 1C, in which there is shown the same laser 15 as was shown in FIG. 1B, impinging on the target 10 tilted at an angle, thereby presenting a smaller target to the tilted beam, such that a percentage of the power spills over the edge of the target. The amount of spilled power is measured by the power meter 16, which could include a power measurement element catching reflection of the beam outside of the target. The same scenario would occur in the normal incidence arrangement of FIG. 1B, if the target were smaller. The allowable spillage for the described laser power transmission systems is defined by the amount of power permitted to enter the surroundings around the target, and this level of power is defined according to the regulatory regulation applicable in the geographical location where the system is authorized to be used. An indication of the regulatory status of the system, or the geographical location of where the system is authorized to be used may be conveyed to the user by means of either labels attached to at least one component of the system, or by warning notifications in the user manual, or by both. According to the current regulation applicable in Israel as well as many other countries, this level is limited to class 1, class 1m and class 2 lasers for general public exposure. Higher power lasers are typically classified as class 3R lasers, even higher power lasers, capable of causing injuries are classified as class 3B, and the highest risk lasers are categorized as class 4 lasers. Lasers above 500 mW CW for many of the wavelengths in common use may cause injuries to the eye and skin and are typically classified as either class 3B or class 4 lasers. This leads to the definition of a parameter used in this disclosure to define beam size in relation to safe use of the beam, known as D_{class3B}. D_{class3B} is defined as the effective diameter of the cross-section of a beam, beyond which the beam contains a total power level of no more than the allowable limit of a class 3B laser. Therefore, for a laser beam incident on a target which absorbs all of those parts of the beam impinging thereon, the value of D_{class3B} will be the beam diameter beyond which the power of the beam exceeds the allowed level of a class 3B laser.

The target size should be at least as large as the class 3B beam diameter, D_{class3B}, divided by the cosine of the maximal receiver field of view (FOVₘₐₓ), i.e., the maximal angle from the normal, at which the receiver is capable of receiving power.

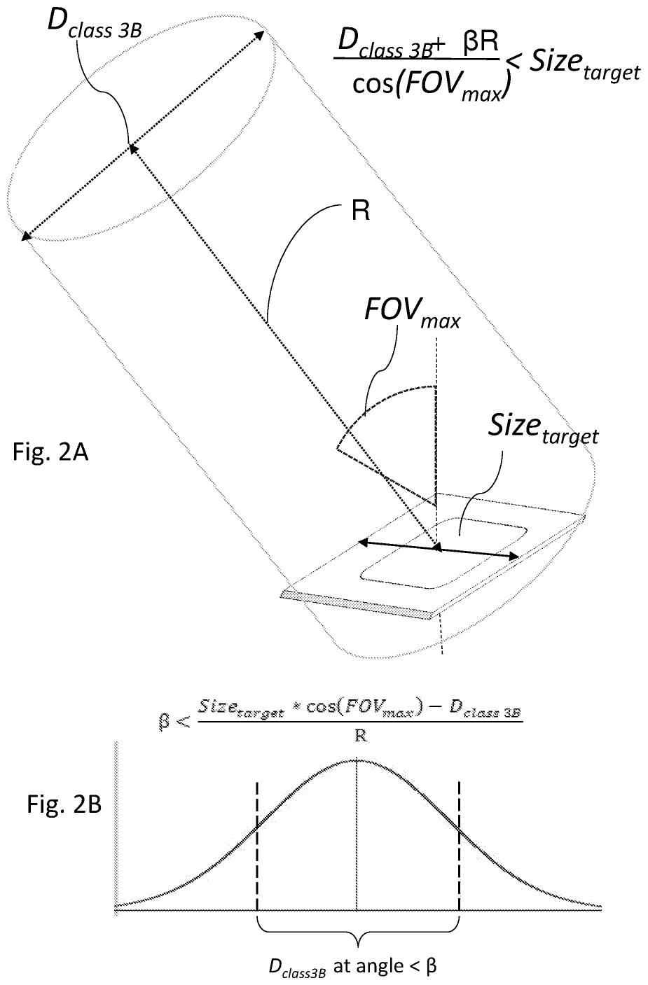

Reference is now made to FIG. 2A, where, for the tilted beam example of FIG. 1C, the size of the target which would ensure that no more than the power of a class 3B laser is emitted into the surroundings, is given by:

$$\frac{{D}_{class 3 B}}{cos ( {FOV}_{max} )} < {Size}_{target}$$

The pointing accuracy of the laser and the beam deflection unit is generally imperfect as a result of various factors, including limited laser pointing accuracy, mechanical vibrations within the system itself, and the finite accuracy of the beam deflection unit. Furthermore, for a high angular speed beam deflector, the mass of the mirror may be such that it cannot follow the desired position corrections issued by the controller, sufficiently rapidly to maintain the desired angular position, but may show a time lag which is translated into a positional inaccuracy. Variations in the beam deflection unit typically also arise as a result of the intrinsic nature of control circuitry. Firstly, the actuating motor of the mirror, or the driving circuits may be limited such that there are discrete intervals between defined positions. The motor may be a stepping motor, or the mirror may be magnetically controlled by a magnetic force generated by a current source, or it may have a piezoelectric driver, or voice coil drivers, or any other suitable mirror driving mechanism. In any such motor, the A/D circuits in the voltage or current drives will have discrete steps, however fine, and the control circuits in general therefore have a defined accuracy, besides being susceptible to noise effects. While the angular resolution of these discrete positions may be very small, when applied to a laser beam projected by the mirror to a receiver across a room of several meters, each control step may result in motion of the beam by millimeters or more. Additionally, the constant error correction of the feedback loop of the mirror control results in aiming jitter, which also adds to reduction of the absolute aiming accuracy of the beam. The beam pointing errors arising from analog-digital and digital-analog conversions, from these feedback inaccuracies, and from mirror driver noise may all add up to a level which determines the size of the target necessary to keep the beam from allowing power at a dangerous level to be propagated into the surroundings of the receiver. Thus, if the receiver is moved by an amount totaling less than the beam step size plus the beam jitter, the safety of the system is maintained so long as the target size is sufficient to limit the additional beam spillage resulting from these additional factors. If the receiver motion is more than the beam step size plus the beam jitter, then the control system should correct the mirror angle by the number of discrete angular steps necessary to follow the mirror motion, all the time trying to keep the beam centered on the target, but still subject to the limitation that the target size must be large enough to keep any beam spillage within the regulatory allowed power level.

The pointing inaccuracy B of a laser beam may be measured in microradians, as the angle whose tangent is the deviation of the beam's center relative to the center of the photovoltaic cell, divided by the operating range:

$$β = {tan}^{- 1} ( {σ}_{beam position relative to PV center} / Range )$$

Thus, accuracy of the beam deflection device is dependent on many factors, including its mass, speed, digital/analog converter, driving electronics, size, and other factors. In another aspect of the current invention, the size of the target must be increased by the angular pointing inaccuracy multiplied by the maximal transmission range, so that:

$$\frac{{D}_{class 3 B} + β R}{cos ( {FOV}_{max} )} < {Size}_{target}$$

D_{class 3B} is typically measured in meters,
β is typically measured in radians,
R is the maximal range at which the system is intended to transmit to the receiver,
FOV is the maximal angle supported by the receiver, typically measured in radians, and
Size_{target} Size_{target} is the target's minimal dimension, typically measured in meters.

Rearranging this relationship, the deflection unit must be able to aim the laser with an accuracy β, measured in radians, such that:

$$β < \frac{{Size}_{target} ⋆ cos ( {FOV}_{max} ) - {D}_{class 3 B}}{R} .$$

This expression is shown in the graph of FIG. 2B, where the limits of the Class 3B laser are shown on a graph of the beam power plotted across the beam profile. Note that in some implementations, the safety diameter of the laser, D_{class 3B}, may be different for the two perpendicular laser axes.

The receiver to be charged, housing the target photovoltaic cell, may be held in a person's hand or may otherwise be in a state of motion in the course of being charged. Movement may be slight, or may involve being carried across or out of the room. The ability of the laser system to continue charging the device depends on the rate of movement. To be able to safely and accurately charge a moving target, the system detects a movement of the target. If the movement is typically less than 10% of the target size as specified below, the system corrects the aim of the beam deflection unit. If the movement is greater than the target size, the system is adapted to reduce the beam power to a safe level. This reduction to a safe level prevents the beam from causing harm to the person carrying the device, or to others in the immediate area. After reduction of the beam's power to a safe level, the system may re-establish correct aiming of the beam onto the target and resume lasing at higher power.

Accuracy β for a correction movement when correcting the aim of the beam deflection unit should be

$$β < \frac{{Size}_{target} ⋆ cos ( {FOV}_{max} ) - {D}_{class 3 B}}{R} ,$$

and preferably 25% of that value or less.

The deflection unit must be able to aim the laser with an accuracy at least as good as the value given by this equation. Before powering the receiver, however, the deflection unit performs a search to locate the receiver by aiming the laser beam in different directions. The search may be performed with a lower accuracy, i.e., a larger β, which allows for faster movement of the deflection unit and scanning of a larger solid angle in a shorter amount of time.

In a specific implementation, the vicinity of the transmitter is first scanned, by pointing the beam deflection unit in various directions in order to roughly locate receivers. Typically, areas of higher probability of finding a receiver are scanned first and if no suitable receiver is found in the high probability areas, then the entire field of view is scanned. The entire field of view scan is typically performed in an ordered manner such as a raster scan or an approximated spiral.

During this stage, the deflection unit moves more rapidly, in order to quickly detect the approximate position of a receiver (if any). In order to enable such fast scanning step, the beam deflection unit, typically a mirror, should have a first mode of operation allowing it to move rapidly from one direction to another.

Scan procedures can be classified into two categories: detection scan and shape recognition scan. The goal of a detection scan is to locate at least one approximate coordinate for every valid receiver in the room in order to estimate its general location. The choice of the scan pattern will determine the full coverage time, coverage area, resolution and location preference. The shape recognition scan is required to create a defined resolution scan of a receiver area.

A spiral pattern is a good solution for a system in which the FOV (field of view) boundaries are elliptic, approximately elliptic, or circular. The scan can be run from a point inside the FOV towards the boundaries or from the boundaries towards the inside. In terms of detection time, a scan covering the center of the spiral first gives preference to receivers in the center of the FOV. A scan first covering the outer parts of the field gives preference to receivers in the outer part of the FOV. Complex spirals covering different portions of the FOV at different times may also be used.

The resolution of the spiral can be determined by drawing a radius from the center point of the spiral and measuring the distances between its intersection with the spiral. The duration of the spiral scan is defined by its total length and by the velocity in each point of the spiral, since the velocity may change as a function of the location within the FOV. The higher the resolution and the total spiral radius, the longer time it will take to run from start to finish. For a shape recognition scan, the spiral gives the advantage of being able to stop the scan when a full cycle is completed, without any retro reflective points, assuming the shape is continuous.

Another scan pattern that may be used is one in which a periodical function is generated in each of the two scan axis. These patterns will be fit, for example, for systems in which the field of view boundaries are rectangular. The amplitude and phase of each Harmonic component and basic frequency of each of the functions can be altered in order to create a variety of two-dimensional patterns. This kind of pattern is easy to implement. It may be used in detection scans to give a preference to an area of the field of view which is not necessarily its center. In shape recognition scans, the pattern can be set to be grid-like to create a scan that does not depend on the shape orientation. The time duration of the pattern can be calculated from the basic frequencies of each of the periodical functions, and can be infinite if the ratio of some of the frequencies is approximately irrational. The time duration increases if the required resolution is finer, but can be decreased by using higher frequencies. Using a single harmonic component in each function simplifies the scan procedure, assuming the control system is approximately an LTI (linear time-invariant) system.

One more method that is specific for shape recognition is a scan in which the pattern is not calculated a priori, but as a function of a recorded retro-reflector signal. For example, when recognizing the shape of the retroreflector tape, time can be saved by scanning only the retro-reflective area of the tape and not the non-reflective points around it, or running the pattern only on the tape edges.

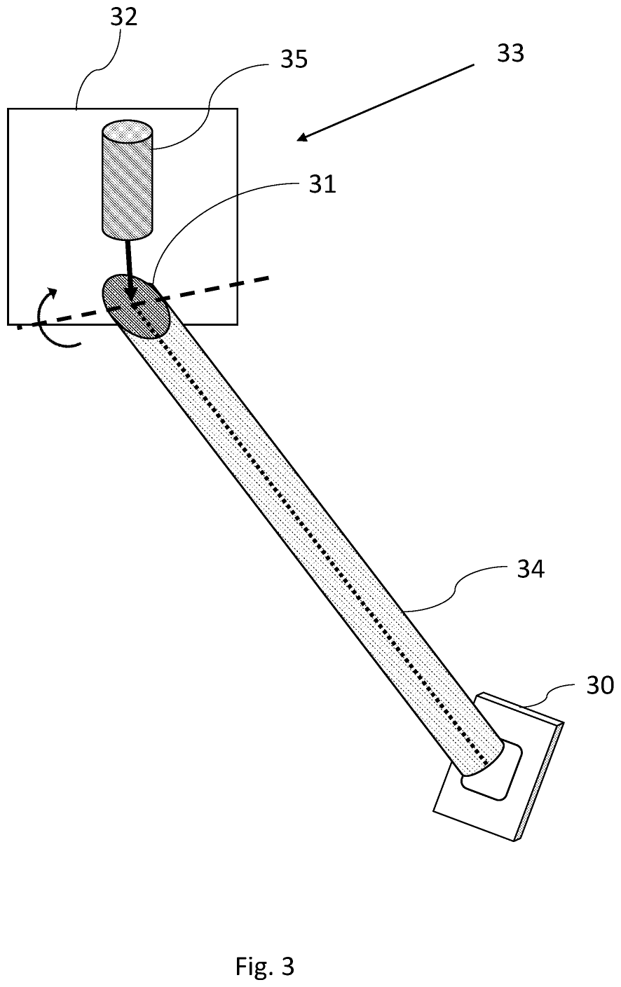

Reference is now made to FIG. 3, which is a schematic drawing showing the transmitter 33, including the beam deflection unit 31 typically placed within the transmitter casing 32. The laser beam 34, generated by the laser 35, is deflected by the mirror in the beam deflection unit 31, and exits the transmitter 33 such that it impinges on the target/receiver 30.

The scanning mirror 31 is located close to the transmitter's output window, which may be fragile. Should the window be broken, the mirror on the beam deflection unit may pose a danger to a finger which may be inserted into the laser casing 32. To prevent injury, the mass and the moment of inertial of the moving part of the mirror should be kept below a limit and likewise for the maximal rotation speed. This maximum rotational speed, measured in degrees/second, is given by:

$$\frac{N}{132000} + \frac{M ⋆ {r}^{\text{?}} ⋆ {N}^{2}}{2.16 ⋆ {10}^{14}} < 1$$

$$\text{?} \text{indicates text missing or illegible when filed}$$

where N is the maximum rotational speed in degrees/second,
r is the radius of the mirror motion, measured in mm, and
M is the mass measured in grams.

It is appreciated by persons skilled in the art that the present invention is not limited by what has been particularly shown and described hereinabove. Rather the scope of the present invention includes both combinations and subcombinations of various features described hereinabove as well as variations and modifications thereto which would occur to a person of skill in the art upon reading the above description and which are not in the prior art.

We claim:

1. An optical wireless power transmission system for transmitting a beam of optical power, the system comprising:
a transmitter comprising an orientable mirror having an operational field of view, the mirror orientation being electronically controlled by an input electronic signal, the transmitter adapted for transmitting the beam of optical power to a receiver comprising a photovoltaic cell adapted to convert the optical power of the beam to electrical power, at least the photovoltaic cell and its surround constituting a target;
wherein the electronically controlled mirror has an aiming accuracy such that the angular deviation of a beam reflected from the mirror, from a direction intended by the electronic control, is smaller than:
$$\frac{{Size}_{target} ⋆ cos ( {FOV}_{max} ) - {D}_{class 3 B}}{R} ,$$
and where:
Size_{target} is a distance between the two closest points on opposite edges of the target;
FOVₘₐₓ is the maximal angle between the beam and the normal to a surface of the photovoltaic cell, at which the receiver can receive a predetermined level of power transmission;
D_{class 3B} is an effective diameter of a cross section of the beam, outside of which the beam contains a total optical power within the limits of a class 3B laser at the wavelength of the beam of optical power; and
R is the maximum range of a receiver to which the system is intended to transmit.

2. An optical wireless power transmission system according to claim 1, wherein the target comprises the minimal lateral dimension of the face of the receiver in or on which the photocell is mounted.

3. An optical wireless power transmission system according to either of the previous claims, wherein the mirror aiming accuracy is such that when the electronic control aims the mirror at the central region of the photovoltaic cell, the maximum optical power transmitted into the environment is less than the power limit allowed for a class 3B laser.

4. An optical wireless power transmission system according to any one of the previous claims, wherein the maximum optical power transmitted into the environment arises from impingement of the beam beyond the edges of the target.

5. An optical wireless power transmission system according to any one of the previous claims, wherein the optical power transmitted into the environment comprises parts of the beam reflected off a surface of the receiver outside the bounds of the target.

6. An optical wireless power transmission system according to any one of claims 1 to 4, wherein the optical power transmitted into the environment comprises transmitted parts of the beam spilling over the edges of the receiver.

7. An optical wireless power transmission system according to any one of the previous claims, wherein the angular deviation of a beam reflected from the mirror, from a direction intended by the electronic control of the electronically controlled mirror, arises from jitter in the input electronic signal.

8. An optical wireless power transmission system according to any of claims 1 to 6, wherein the angular deviation of a beam reflected from the mirror, from a direction intended by the electronic control of the electronically controlled mirror, arises from at least one of electronic feedback loop jitter, driver noise level, conversion resolution of digital circuits generating the input electronic signal, and circuit noise.

9. An optical wireless power transmission system according to any of claims 1 to 6, wherein the angular deviation of a beam reflected from the mirror, from a direction intended by the electronic control of the electronically controlled mirror, arises from step increments of a mechanical driver generating the orientation of the mirror.

10. An optical wireless power transmission system according to any of claims 1 to 6, wherein the angular deviation of a beam reflected from the mirror, from a direction intended by the electronic control of the electronically controlled mirror, arises from mechanical vibration of the mirror.

11. An optical wireless power transmission system according to any of the previous claims, wherein the maximum angular rotational speed of the mirror is given by the expression:
$$\frac{N}{132000} + \frac{M ⋆ {r}^{2} ⋆ {N}^{\text{?}}}{2.16 ⋆ {10}^{14}} < 1$$
$$\text{?} \text{indicates text missing or illegible when filed}$$
where:
N is the angular rotational speed in degrees per second,
r is the radius of the mirror motion, measured in mm, and
M is the mass of the mirror measured in grams.

12. An optical wireless power transmission system for transmitting a beam of optical power, the system comprising:
a transmitter comprising an orientable mirror electronically controlled by an input electronic signal, the transmitter adapted for transmitting the beam of optical power to a receiver comprising a photovoltaic cell adapted to convert the optical power of the beam to electrical power, at least the photovoltaic cell and its border surround constituting a target;
wherein the electronically controlled mirror is configured to have an aiming accuracy at least such that the angular deviation of a beam from a direction intended for its propagation by the electronically controlled mirror, is such that the level of optical power transferred into the surroundings, when a beam having the maximum power which the system can transmit is aimed at the target, does not exceed that allowed by a regulatory requirement applicable to a location where the system is authorized to operate.

13. An optical wireless power transmission system according to claim 12, wherein the level of regulatory requirement is the power limit allowed for a class 3B laser.

14. An optical wireless power transmission system according to either one of claims 12 and 13, wherein the level of optical power not absorbed by the photovoltaic cell and its border surround comprises power reflected from the surface of the receiver outside of the photovoltaic cell and its border surround.

15. An optical wireless power transmission system according to either one of claims 12 and 13, wherein the level of optical power not absorbed by the photovoltaic cell and its border surround comprises parts of the optical beam spilling over the edges of the receiver.

16. An optical wireless power transmission system according to any one of claims 12 to 15, wherein the angular deviation of a beam reflected from the mirror, from a direction intended by the electronic control of the electronically controlled mirror, arises from jitter in the input electronic signal.

17. An optical wireless power transmission system according to any one of claims 12 to 15, wherein the angular deviation of a beam reflected from the mirror, from a direction intended by the electronic control of the electronically controlled mirror, arises from at least one of electronic feedback loop jitter, driver noise level, conversion resolution of digital circuits generating the input electronic signal, and circuit noise.

18. An optical wireless power transmission system according to any one of claims 12 to 15, wherein the angular deviation of a beam reflected from the mirror, from a direction intended by the electronic control of the electronically controlled mirror, arises from step increments of a mechanical driver generating the orientation of the mirror.

19. An optical wireless power transmission system according to any of claims 12 to 15, wherein the angular deviation of a beam reflected from the mirror, from a direction intended by the electronic control of the electronically controlled mirror, arises from mechanical vibration of the mirror.

20. An optical wireless power transmission system according to any of claims 12 to 19, wherein at least one element of the system is marked with at least one indication of a regulatory requirement applicable to a location where the system is authorized to operate,

21. An optical wireless power transmission system according to claim 20, wherein the element may be a component part of the system or an operational manual of the system.

22. An optical wireless power transmission system according to any of claims 12 to 21, wherein the regulatory requirement is that the total level of optical power transferred into the environment and not absorbed by the target, Is less than the power limits of a class 3B laser at the wavelength of the beam of optical power.
